(19) United States
(12) Patent Application Publication
(10) Pub. No.: US 2012/0119231 A1
(43) Pub. Date: May 17, 2012

(54) LED PACKAGE STRUCTURE WITH A DEPOSITED-TYPE PHOSPHOR LAYER AND METHOD FOR MAKING THE SAME

(75) Inventors: BILY WANG, HSINCHU CITY (TW); SUNG-YI HSIAO, MIAOLI COUNTY (TW); YU-JEN CHENG, TAINAN CITY (TW); JACK CHEN, MIAOLI COUNTY (TW)

(73) Assignee: HARVATEK CORPORATION, HSINCHU CITY (TW)

(21) Appl. No.: 13/181,662

(22) Filed: Jul. 13, 2011

(30) Foreign Application Priority Data
Nov. 17, 2010 (TW) 99139508

(51) Int. Cl. H01L 33/08; H01L 33/58

(52) U.S. Cl. 257/88; 438/27; 257/E33.012; 257/E33.059

(57) ABSTRACT

An LED package structure with a deposited-type phosphor layer includes a substrate unit, a light-emitting unit and a package unit. The substrate unit includes at least one circuit substrate. The light-emitting unit includes a plurality of LED chips disposed on and electrically connected to the at least one circuit substrate. The package unit includes at least one package resin body formed by a mold structure. The at least one package resin body is formed on the at least one circuit substrate to cover the LED chips, and the at least one package resin body includes a continuous phosphor layer formed therein and deposited on outer surfaces of the LED chips by centrifugal force. Hence, the instant disclosure provides the continuous phosphor layer with the deposited phosphor powders for covering the outer surfaces of the LED chips, thus the light-emitting efficiency of the LED package structure can be increased actually.

### BACKGROUND OF THE INVENTION

1. Field of the Invention

The instant disclosure relates to an LED package structure and a method for making the same, and more particularly, to an LED package structure with a deposited-type phosphor layer and a method for making the same.

2. Description of Related Art

Referring to FIG. 1, a known LED package structure includes a circuit substrate 1a, an LED chip 2a disposed on the at least one circuit substrate 1a, two lead wires 3a, and a package resin body 4a including phosphor powders 40a.

The LED chip 2a has a light-emitting surface 20a opposite to the at least one circuit substrate 1a. The LED chip 2a has a positive electrode area 21a and a negative electrode area 22a electrically connected to two corresponding positive and negative electrode areas (11a, 12a) of the at least one circuit substrate 1a via the two lead wires 3a, respectively. Moreover, the package resin body 4a with the phosphor powders 40a covers the LED chip 2a and the two lead wires 3a for protecting the LED chip 2a. Therefore, when the LED chip 2a is a blue LED, blue light generated by the blue LED can pass through the package resin body 4a with the phosphor powders 40a to generate white light.

However, the phosphor powders 40a should not be uniformly mixed into the package resin body 4a. Hence, when the blue light generated by the blue LED passes through the package resin body 4a with the phosphor powders 40a to generate white light, the condensing capability and the color and luster of the white lights are bad and non-uniform.

### SUMMARY OF THE INVENTION

One particular aspect of the instant disclosure is to provide an LED package structure with a deposited-type phosphor layer and a method for making the same.

One embodiment of the instant disclosure provides an LED package structure with a deposited-type phosphor layer, comprising: a substrate unit, a light-emitting unit and a package unit. The substrate unit includes at least one circuit substrate. The light-emitting unit includes a plurality of LED chips disposed on and electrically connected to the at least one circuit substrate. The package unit includes at least one package resin body formed by a mold structure. The at least one package resin body is formed on the at least one circuit substrate to cover the LED chips, and the at least one package resin body includes a continuous phosphor layer formed therein and deposited on outer surfaces of the LED chips by centrifugal force.

For example, the continuous phosphor layer is composed of a plurality of phosphor powders, and the at least one package resin body is formed by mixing light-permitting silicon with the phosphor powders. The continuous phosphor layer is composed of a plurality of phosphor powders, and the at least one package resin body is formed by mixing light-permitting epoxy with the phosphor powders. The at least one package resin body includes a bottom resin portion and a plurality of lens resin portions integrally formed on the bottom resin portion, and each lens resin portion is disposed above each LED chip and corresponds to each LED chip. The mold structure includes a top mold and a bottom mold mated with the top mold, the top mold has a bottom portion tightly contacting the bottom surface of the at least one circuit substrate, the bottom mold has a plurality of lens grooves formed on a top portion thereof to respectively correspond to the lens resin portions, and each lens resin portion has an outer surface tightly contacting the inner surface of each lens groove. The top mold includes at least two first positioning elements disposed on the bottom portion thereof, and the bottom mold includes at least two second positioning elements disposed on the top portion thereof to respectively correspond to and mate with the two first positioning elements. The top mold includes an encircled protrusion disposed on the bottom portion thereof and a plurality of through grooves formed on the encircled protrusion, and the encircled protrusion tightly contacts the top surface of the bottom mold.

Another embodiment of the instant disclosure provides a method for making an LED package structure with a deposited-type phosphor layer, comprising the steps of: (a) providing at least one circuit substrate and a plurality of LED chips, wherein the LED chips are disposed on and electrically connected to the at least one circuit substrate; (b) providing a mold structure including a top mold and a bottom mold separated from the top mold, wherein the top mold has a first receiving groove formed on a bottom portion thereof, and the bottom mold has a second receiving groove formed on a top portion thereof to correspond to the first receiving groove; (c) covering the LED chips and filling the second receiving groove with liquid package colloid including phosphor powders; (d) overturning the at least one circuit substrate and placing the at least one circuit substrate on the top portion of the bottom mold for receiving the LED chips in the second receiving groove; (e) placing the top mold on the bottom mold and mating the top mold with the bottom mold for positioning the at least one circuit substrate between the top mold and the bottom mold; (f) moving the mold structure by centrifugal force for depositing the phosphor powders on outer surfaces of the LED chips to form a continuous phosphor layer; (g) curing the mold structure for solidifying the liquid package colloid to form a solid package resin body covering the LED chips; and then (h) separating the top mold from the bottom mold and removing the at least one circuit substrate with the LED chips from the mold structure. Moreover, before the step (c), the method further comprises: cleaning the top mold, the bottom mold and the at least one circuit substrate; spraying mold-release agent on the surfaces of the top mold and the bottom mold; and curing the top mold, the bottom mold and the at least one circuit substrate.

Another embodiment of the instant disclosure provides a method for making an LED package structure with a deposited-type phosphor layer, comprising the steps of: (a) providing at least one circuit substrate and a plurality of LED chips, wherein the LED chips are disposed on and electrically connected to the at least one circuit substrate; (b) providing a mold structure including a top mold and a bottom mold separated from the top mold, wherein the top mold has a first receiving groove formed on a bottom portion thereof, and the bottom mold has a second receiving groove formed on a top portion thereof to correspond to the first receiving groove; (c) covering the LED chips and filling the second receiving groove with liquid package colloid including phosphor powders; (d) overturning the at least one circuit substrate and placing the at least one circuit substrate on the top portion of the bottom mold for receiving the LED chips in the second receiving groove; (e) placing the top mold on the bottom mold and mating the top mold with the bottom mold for positioning the at least one circuit substrate between the top mold and the bottom mold; (f) simultaneously (1) moving the mold structure by centrifugal force for depositing the phosphor powders on outer surfaces of the LED chips to form a continuous phosphor layer and (2) curing the mold structure for solidifying the liquid package colloid to form a solid package resin body covering the LED chips; and (g) separating the top mold from the bottom mold and removing the at least one circuit substrate with the LED chips from the mold structure. Moreover, before the step (c), the method further comprises: cleaning the top mold, the bottom mold and the at least one circuit substrate; spraying mold-release agent on the surfaces of the top mold and the bottom mold; and curing the top mold, the bottom mold and the at least one circuit substrate.

Therefore, the instant disclosure provides the continuous phosphor layer with the deposited phosphor powders for covering the outer surfaces of the LED chips, thus the light-emitting efficiency of the LED package structure can be increased actually.

To further understand the techniques, means and effects the instant disclosure takes for achieving the prescribed objectives, the following detailed descriptions and appended drawings are hereby referred, such that, through which, the purposes, features and aspects of the instant disclosure can be thoroughly and concretely appreciated. However, the appended drawings are provided solely for reference and illustration, without any intention that they be used for limiting the instant disclosure.

### BRIEF DESCRIPTION OF THE DRAWINGS

FIG. 1 shows a cross-sectional, schematic view of the LED package structure according to the related art;

FIGS. 2-1, 2-2 show a flowchart of the method for making the LED package structure according to the instant disclosure;

FIGS. 2A to 2I show cross-sectional, schematic views of the LED package structure according to the instant disclosure, at different stages of the making processes, respectively (FIG. 2D shows a cross-sectional view taken along the section line A-A of FIG. 2C, and FIG. 2G shows an enlarged view taken on part A of FIG. 2F);

FIG. 3A shows a perspective, schematic view of the LED package structure according to the instant disclosure; and

FIG. 3B shows a cross-sectional view taken along the section line B-B of FIG. 3A.

### DETAILED DESCRIPTION OF THE PREFERRED EMBODIMENTS

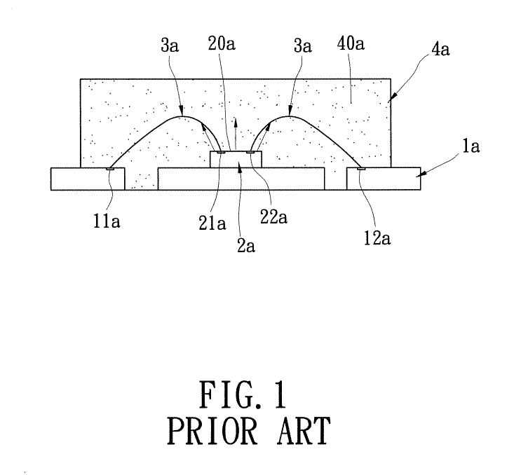

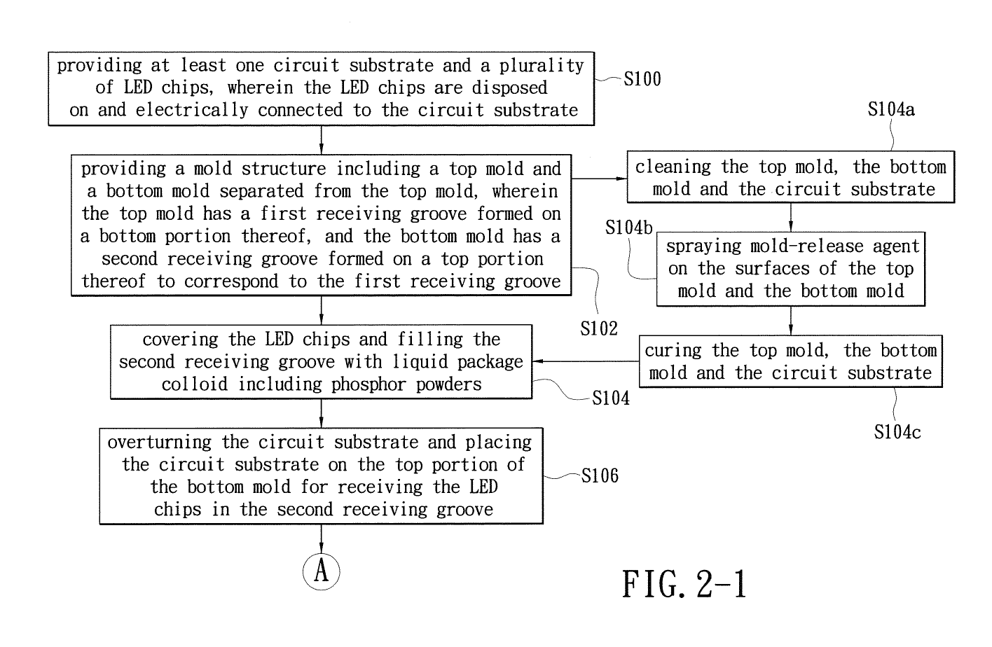

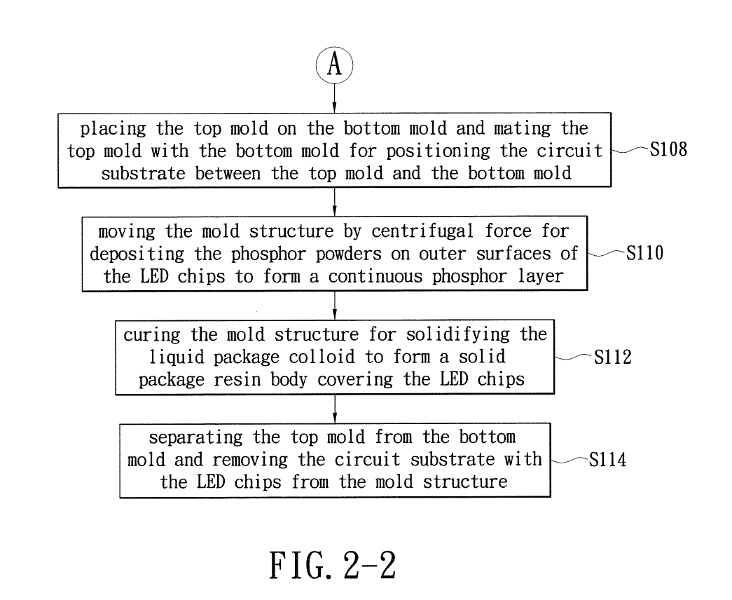

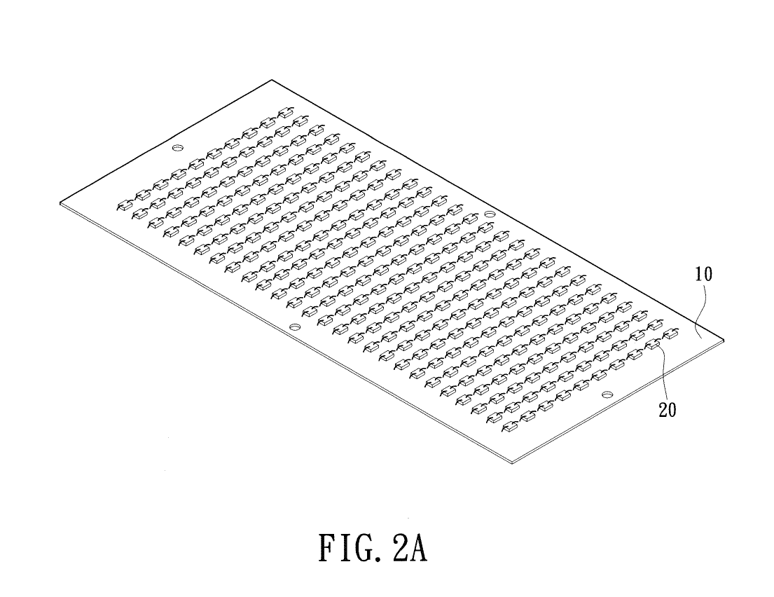

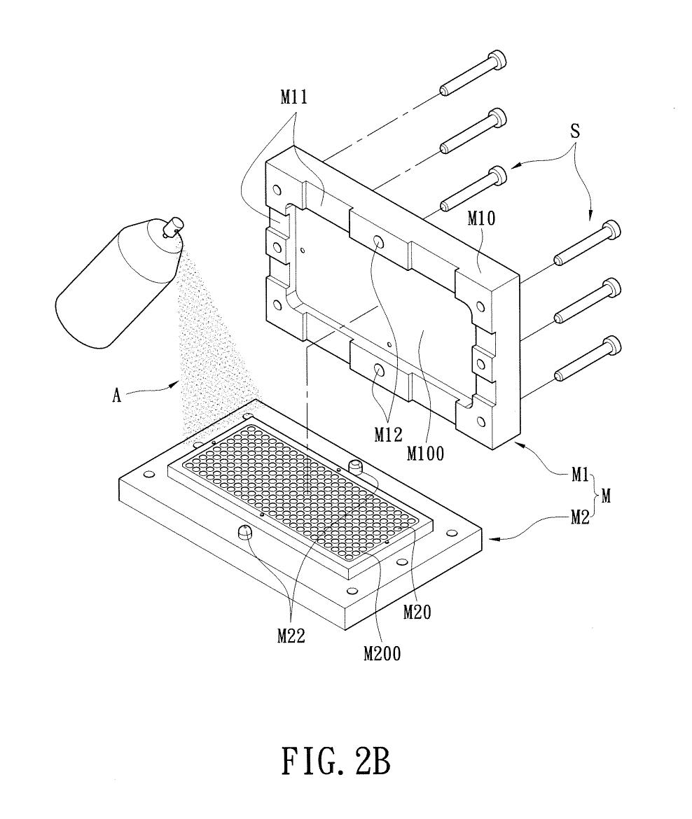

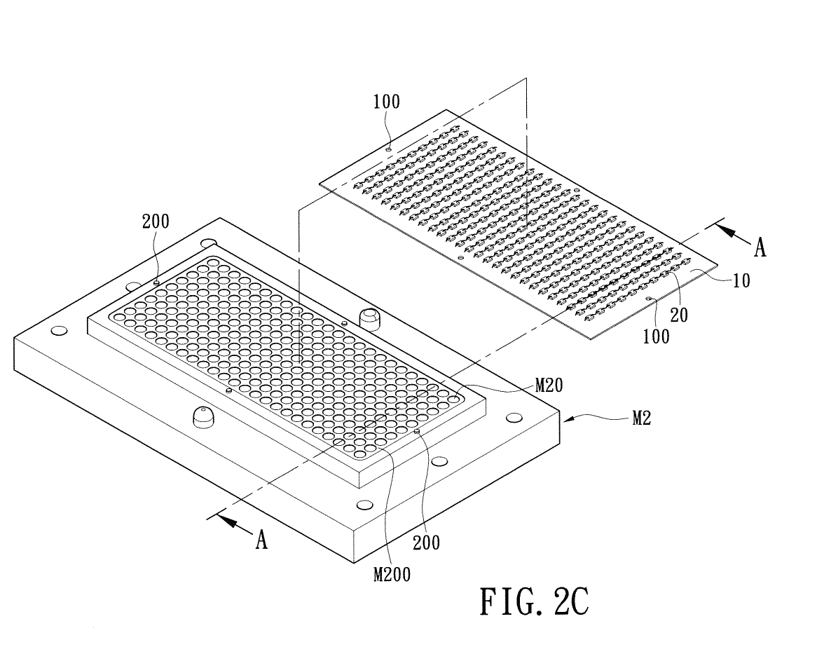

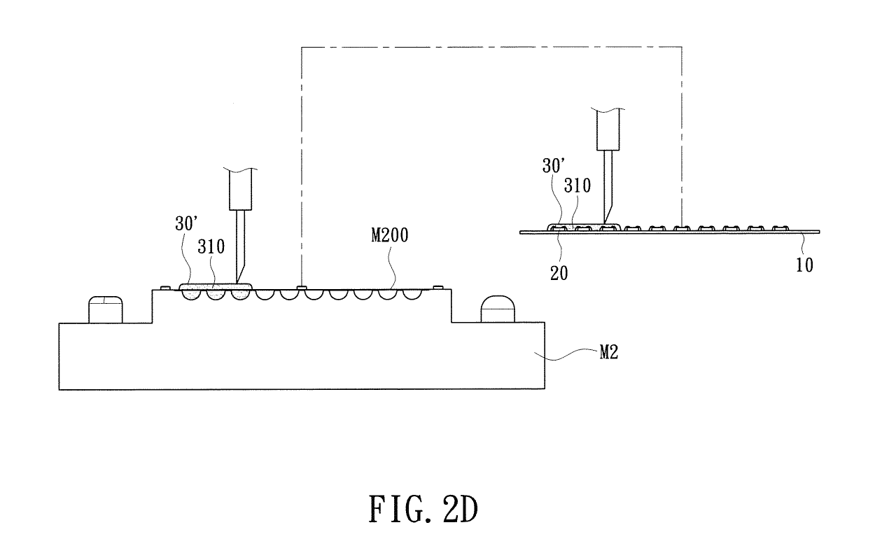

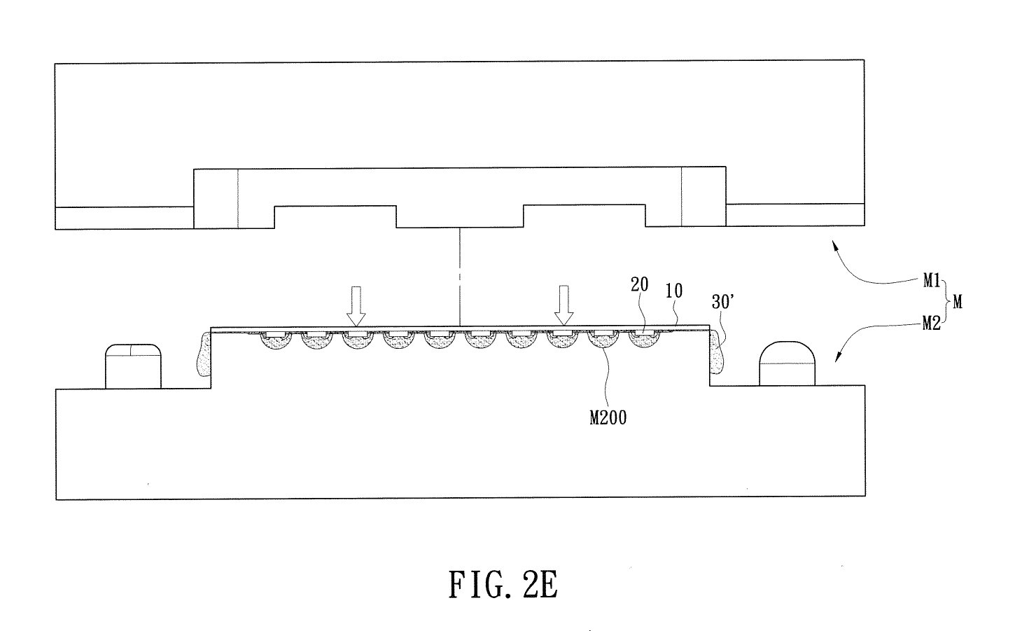

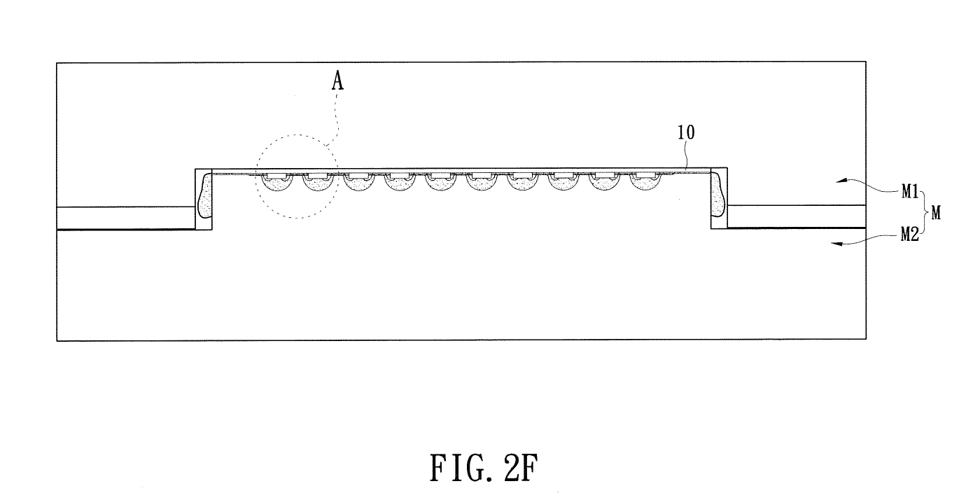

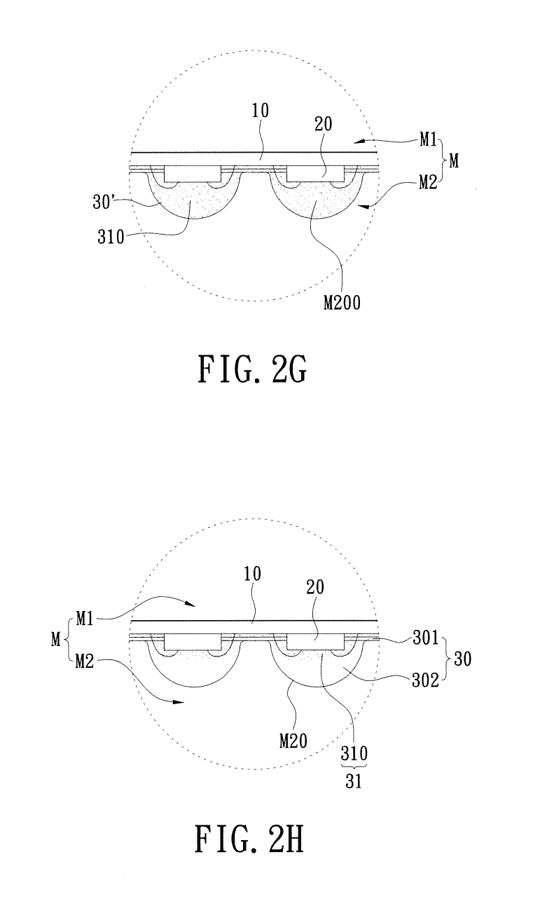

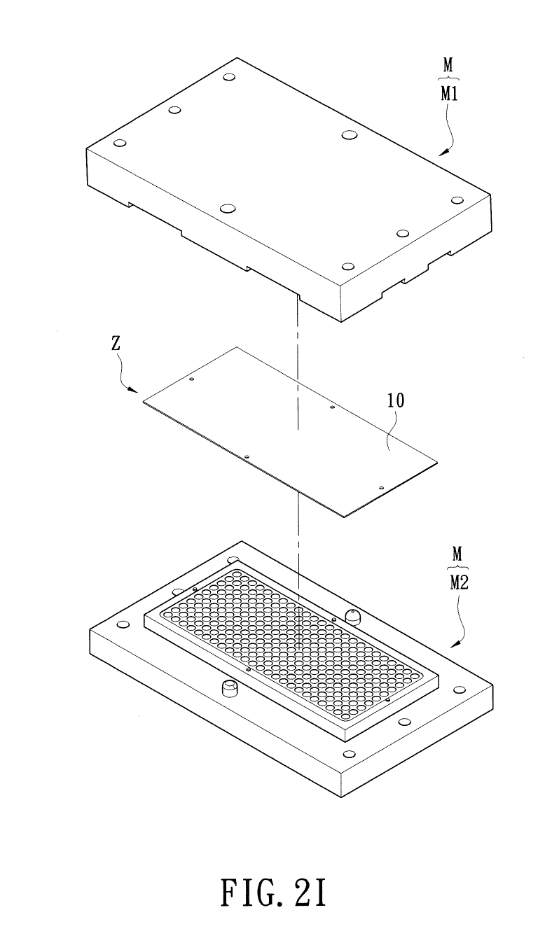

Referring to FIGS. 2-1, 2-2 and 2A-2I, where the instant disclosure provides a method for making an LED package structure Z with a deposited-type phosphor layer, comprising the following steps of:

The step S100 is that: referring to FIGS. 2-1, 2-2 and 2A, providing at least one circuit substrate 10 and a plurality of LED chips 20 (bare die state), wherein the LED chips 20 are disposed on and electrically connected to the at least one circuit substrate 10. For example, the at least one circuit substrate 10 has a predetermined circuit track formed on the top surface thereof, and each LED chip 20 can be electrically connected to the circuit track of the at least one circuit substrate 10 by a wire-bonding method or a flip-chip method.

The step S102 is that: referring to FIGS. 2-1, 2-2 and 2B, providing a mold structure M including a top mold M1 and a bottom mold M2 separated from the top mold M1, wherein the top mold M1 has a first receiving groove M100 formed on a bottom portion thereof, and the bottom mold M2 has a second receiving groove M200 formed on a top portion thereof to correspond to the first receiving groove M100. For example, the top mold M1 and the bottom mold M2 can be assembled together by a plurality of securing elements S such as screws. In addition, the top mold M1 includes an encircled protrusion M10 disposed on the bottom portion thereof and a plurality of through grooves M11 formed on the encircled protrusion M10, and the encircled protrusion M10 tightly contacts the top surface of the bottom mold M2, thus the top mold M1 and the bottom mold M2 can be tightly mated with each other. Moreover, the top mold M1 includes at least two first positioning elements M12 disposed on the bottom portion thereof, and the bottom mold M2 includes at least two second positioning elements M22 disposed on the top portion thereof to respectively correspond to and mate with the two first positioning elements M12.

The step S104 is that: referring to FIGS. 2-1, 2-2 and 2B-2D, covering the LED chips 20 and filling the second receiving groove M200 with liquid package colloid 30′ including phosphor powders 310. For example, before the step S104, the method further comprises: cleaning the top mold M1, the bottom mold M2 and the at least one circuit substrate 10 with or without the LED chips 20 (S104(a)), spraying mold-release agent A on the surfaces of the top mold M1 and the bottom mold M2 (S104(b)), and then curing (or baking) the top mold M1, the bottom mold M2 and the at least one circuit substrate 10 with or without the LED chips 20 (S104(c)) to remove unnecessary moisture.

The step S106 is that: referring to FIGS. 2-1, 2-2, 2C and 2E, overturning the at least one circuit substrate 10 and placing the at least one circuit substrate 10 on the top portion of the bottom mold M2 for receiving the LED chips 20 in the second receiving groove M200. For example, the at least one circuit substrate 10 includes at least two first positioning holes 100 (the instant disclosure provides four first positioning holes 100 as shown in FIG. 2C), and the bottom mold M2 includes at least two positioning posts 200 (the instant disclosure provides four positioning posts 200 as shown in FIG. 2C) formed on the top portion thereof and corresponding to the two first positioning holes 100. Hence, when the at least one circuit substrate 10 is overturned and the two first positioning holes 100 are respectively mated with the two positioning posts 200, a downward force (as the downward arrow shown in FIG. 2E) can be acted on the bottom side of the at least one circuit substrate 10 to press the at least one circuit substrate 10, thus the liquid package colloid 30′ is fully filled between the at least one circuit substrate 10 and the bottom mold M2 (it means that a gap between the at least one circuit substrate 10 and the bottom mold M2 is full of the liquid package colloid 30′) and unnecessary liquid package colloid 30′ is extracted out of the at least one circuit substrate 10 or the bottom mold M2.

The step S108 is that: referring to FIGS. 2-1, 2-2, 2F and 2G, placing the top mold M1 on the bottom mold M2 and mating the top mold M1 with the bottom mold M2 for positioning the at least one circuit substrate 10 between the top mold M1 and the bottom mold M2. For example, the top mold M1 and the bottom mold M2 can be assembled together by a plurality of securing elements S such as screws.

The step S110 is that: referring to FIGS. 2-1, 2-2, 2G and 2H, moving the mold structure M by centrifugal force for depositing the phosphor powders 310 on outer surfaces of the LED chips 20 to form a continuous phosphor layer 31. For example, when the mold structure M is continuously rotated in centrifuge, the phosphor powders 310 can be gradually deposited to form the continuous phosphor layer 31 on the outer surfaces of the LED chips 20.

The step S112 is that: referring to FIGS. 2-1, 2-2, 2G and 2H, curing (or baking) the mold structure M for solidifying the liquid package colloid 30′ to form a solid package resin body 30 covering the LED chips 20. For example, the continuous phosphor layer 31 can be composed of a plurality of phosphor powders 310, and the solid package resin body 30 can be formed by mixing light-permitting silicon or epoxy with the phosphor powders 310. In addition, the solid package resin body 30 includes a bottom resin portion 301 and a plurality of lens resin portions 302 integrally formed on the bottom resin portion 301, and each lens resin portion 302 is disposed above each LED chip 20 and corresponds to each LED chip 20. Moreover, the bottom portion of the top mold M1 tightly contacts the bottom surface of the at least one circuit substrate 10, the bottom mold M2 has a plurality of lens grooves M20 formed on the top portion thereof to respectively correspond to the lens resin portions 302, and each lens resin portion 302 has an outer surface tightly contacting the inner surface of each lens groove M20.

Of course, the steps S100 and S112 can be executed at the same time, thus the mold structure M can be moving by centrifugal force and curing at the same time. In other words, the method comprises simultaneously (1) moving the mold structure M by centrifugal force for depositing the phosphor powders 310 on outer surfaces of the LED chips 20 to form a continuous phosphor layer 31 and (2) curing the mold structure M for solidifying the liquid package colloid 30′ to form a solid package resin body 30 covering the LED chips 20.

The step S114 is that: referring to FIGS. 2-1, 2-2 and 2I, separating the top mold M1 from the bottom mold M2 (or separating the bottom mold M2 from the top mold MD and removing the at least one circuit substrate 10 with the LED chips 20 from the mold structure M.

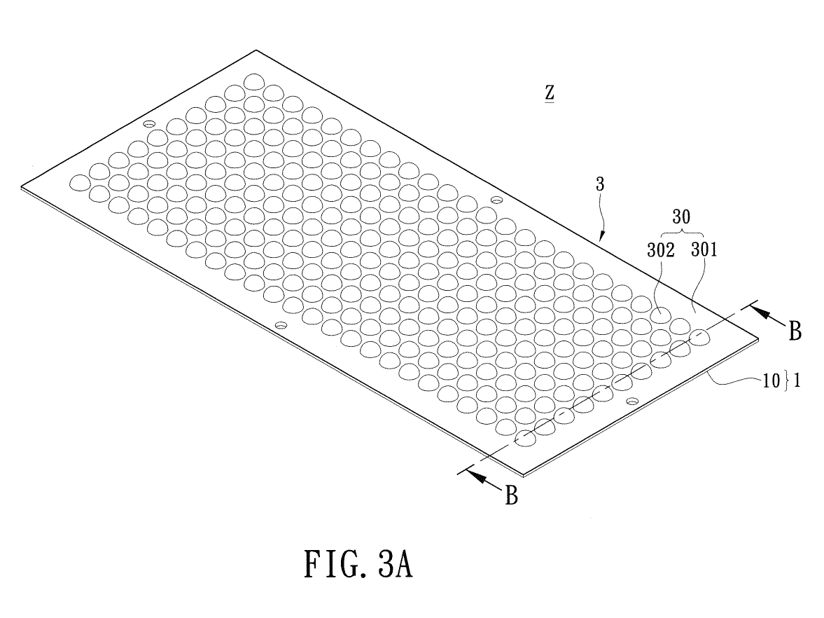

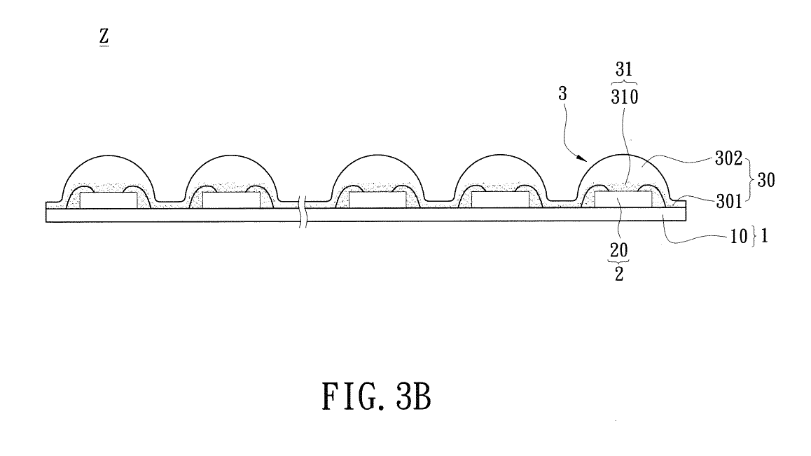

Therefore, referring to FIGS. 3A and 3B, the instant disclosure provides an LED package structure Z with a deposited-type phosphor layer, comprising: a substrate unit 1, a light-emitting unit 2 and a package unit 3.

The substrate unit 1 includes at least one circuit substrate 10. The light-emitting unit 2 includes a plurality of LED chips 20 disposed on and electrically connected to the at least one circuit substrate 10.

The package unit 3 includes at least one package resin body 30 formed by a mold structure M (as shown in FIG. 2B). The at least one package resin body 30 is formed on the at least one circuit substrate 10 to cover the LED chips 20, and the at least one package resin body 30 includes a continuous phosphor layer 31 formed therein and deposited on outer surfaces of the LED chips 20 by centrifugal force.

For example, the continuous phosphor layer 31 can be composed of a plurality of phosphor powders 310, and the at least one package resin body 30 can be formed by mixing light-permitting silicon or epoxy with the phosphor powders 310. In addition, the at least one package resin body 30 includes a bottom resin portion 301 and a plurality of lens resin portions 302 integrally formed on the bottom resin portion 301, and each lens resin portion 302 is disposed above each LED chip 20 and corresponds to each LED chip 20.

Moreover, referring to FIG. 2B, the mold structure M includes a top mold M1 and a bottom mold M2 mated with the top mold M1. The bottom portion of the top mold M1 tightly contacts the bottom surface of the at least one circuit substrate 10, the bottom mold M2 has a plurality of lens grooves M20 formed on the top portion thereof to respectively correspond to the lens resin portions 302, and each lens resin portion 302 has an outer surface tightly contacting the inner surface of each lens groove M20. In addition, the top mold M1 includes an encircled protrusion M10 disposed on the bottom portion thereof and a plurality of through grooves M11 formed on the encircled protrusion M10, and the encircled protrusion M10 tightly contacts the top surface of the bottom mold M2. Furthermore, the top mold M1 includes at least two first positioning elements M12 disposed on the bottom portion thereof, and the bottom mold M2 includes at least two second positioning elements M22 disposed on the top portion thereof to respectively correspond to and mate with the two first positioning elements M12.

In conclusion, one embodiment of the instant disclosure provides an LED package structure with a deposited-type phosphor layer, comprising: a substrate unit, a light-emitting unit and a package unit. The substrate unit includes at least one circuit substrate. The light-emitting unit includes a plurality of LED chips disposed on and electrically connected to the at least one circuit substrate. The package unit includes at least one package resin body formed by a mold structure. The at least one package resin body is formed on the at least one circuit substrate to cover the LED chips, and the at least one package resin body includes a continuous phosphor layer formed therein and deposited on outer surfaces of the LED chips by centrifugal force.

Another embodiment of the instant disclosure provides a method for making an LED package structure with a deposited-type phosphor layer, comprising the steps of: (a) providing at least one circuit substrate and a plurality of LED chips, wherein the LED chips are disposed on and electrically connected to the at least one circuit substrate; (b) providing a mold structure including a top mold and a bottom mold separated from the top mold, wherein the top mold has a first receiving groove formed on a bottom portion thereof, and the bottom mold has a second receiving groove formed on a top portion thereof to correspond to the first receiving groove; (c) covering the LED chips and filling the second receiving groove with liquid package colloid including phosphor powders; (d) overturning the at least one circuit substrate and placing the at least one circuit substrate on the top portion of the bottom mold for receiving the LED chips in the second receiving groove; (e) placing the top mold on the bottom mold and mating the top mold with the bottom mold for positioning the at least one circuit substrate between the top mold and the bottom mold; (f) moving the mold structure by centrifugal force for depositing the phosphor powders on outer surfaces of the LED chips to form a continuous phosphor layer; (g) curing the mold structure for solidifying the liquid package colloid to form a solid package resin body covering the LED chips; and then (h) separating the top mold from the bottom mold and removing the at least one circuit substrate with the LED chips from the mold structure.

Another embodiment of the instant disclosure provides a method for making an LED package structure with a deposited-type phosphor layer, comprising the steps of: (a) providing at least one circuit substrate and a plurality of LED chips, wherein the LED chips are disposed on and electrically connected to the at least one circuit substrate; (b) providing a mold structure including a top mold and a bottom mold separated from the top mold, wherein the top mold has a first receiving groove formed on a bottom portion thereof, and the bottom mold has a second receiving groove formed on a top portion thereof to correspond to the first receiving groove; (c) covering the LED chips and filling the second receiving groove with liquid package colloid including phosphor powders; (d) overturning the at least one circuit substrate and placing the at least one circuit substrate on the top portion of the bottom mold for receiving the LED chips in the second receiving groove; (e) placing the top mold on the bottom mold and mating the top mold with the bottom mold for positioning the at least one circuit substrate between the top mold and the bottom mold; (f) simultaneously (1) moving the mold structure by centrifugal force for depositing the phosphor powders on outer surfaces of the LED chips to form a continuous phosphor layer and (2) curing the mold structure for solidifying the liquid package colloid to form a solid package resin body covering the LED chips; and (g) separating the top mold from the bottom mold and removing the at least one circuit substrate with the LED chips from the mold structure.

Therefore, the instant disclosure provides the continuous phosphor layer with the deposited phosphor powders for covering the outer surfaces of the LED chips, thus the light-emitting efficiency of the LED package structure can be increased actually.

The above-mentioned descriptions merely represent the preferred embodiments of the instant disclosure, without any intention or ability to limit the scope of the instant disclosure which is fully described only within the following claims. Various equivalent changes, alterations or modifications based on the claims of instant disclosure are all, consequently, viewed as being embraced by the scope of the instant disclosure.

What is claimed is:

1. An LED package structure with a deposited-type phosphor layer, comprising:
a substrate unit including at least one circuit substrate;
a light-emitting unit including a plurality of LED chips disposed on and electrically connected to the at least one circuit substrate; and
a package unit including at least one package resin body formed by a mold structure, wherein the at least one package resin body is formed on the at least one circuit substrate to cover the LED chips, and the at least one package resin body includes a continuous phosphor layer formed therein and deposited on outer surfaces of the LED chips by centrifugal force.

2. The LED package structure of claim 1, wherein the continuous phosphor layer is composed of a plurality of phosphor powders, and the at least one package resin body is formed by mixing light-permitting silicon with the phosphor powders.

3. The LED package structure of claim 1, wherein the continuous phosphor layer is composed of a plurality of phosphor powders, and the at least one package resin body is formed by mixing light-permitting epoxy with the phosphor powders.

4. The LED package structure of claim 1, wherein the at least one package resin body includes a bottom resin portion and a plurality of lens resin portions integrally formed on the bottom resin portion, and each lens resin portion is disposed above each LED chip and corresponds to each LED chip.

5. The LED package structure of claim 4, wherein the mold structure includes a top mold and a bottom mold mated with the top mold, the top mold has a bottom portion tightly contacting the bottom surface of the at least one circuit substrate, the bottom mold has a plurality of lens grooves formed on a top portion thereof to respectively correspond to the lens resin portions, and each lens resin portion has an outer surface tightly contacting the inner surface of each lens groove.

6. The LED package structure of claim 5, wherein the top mold includes at least two first positioning elements disposed on the bottom portion thereof, and the bottom mold includes at least two second positioning elements disposed on the top portion thereof to respectively correspond to and mate with the two first positioning elements.

7. The LED package structure of claim 5, wherein the top mold includes an encircled protrusion disposed on the bottom portion thereof and a plurality of through grooves formed on the encircled protrusion, and the encircled protrusion tightly contacts the top surface of the bottom mold.

8. A method for making an LED package structure with a deposited-type phosphor layer, comprising the steps of:
(a) providing at least one circuit substrate and a plurality of LED chips, wherein the LED chips are disposed on and electrically connected to the at least one circuit substrate;
(b) providing a mold structure including a top mold and a bottom mold separated from the top mold, wherein the top mold has a first receiving groove formed on a bottom portion thereof, and the bottom mold has a second receiving groove formed on a top portion thereof to correspond to the first receiving groove;
(c) covering the LED chips and filling the second receiving groove with liquid package colloid including phosphor powders;
(d) overturning the at least one circuit substrate and placing the at least one circuit substrate on the top portion of the bottom mold for receiving the LED chips in the second receiving groove;
(e) placing the top mold on the bottom mold and mating the top mold with the bottom mold for positioning the at least one circuit substrate between the top mold and the bottom mold;
(f) moving the mold structure by centrifugal force for depositing the phosphor powders on outer surfaces of the LED chips to form a continuous phosphor layer;
(g) curing the mold structure for solidifying the liquid package colloid to form a solid package resin body covering the LED chips; and
(h) separating the top mold from the bottom mold and removing the at least one circuit substrate with the LED chips from the mold structure.

9. The method of claim 8, wherein before the step (c), the method further comprises:
cleaning the top mold, the bottom mold and the at least one circuit substrate with the LED chips;
spraying mold-release agent on the surfaces of the top mold and the bottom mold; and
curing the top mold, the bottom mold and the at least one circuit substrate with the LED chips.

10. The method of claim 8, wherein the continuous phosphor layer is composed of a plurality of phosphor powders, and the at least one package resin body is formed by mixing light-permitting silicon with the phosphor powders.

11. The method of claim 8, wherein the continuous phosphor layer is composed of a plurality of phosphor powders, and the at least one package resin body is formed by mixing light-permitting epoxy with the phosphor powders.

12. The method of claim 8, wherein the at least one package resin body includes a bottom resin portion and a plurality of lens resin portions integrally formed on the bottom resin portion, and each lens resin portion is disposed above each LED chip and corresponds to each LED chip.

13. The method of claim 12, wherein the bottom portion of the top mold tightly contacts the bottom surface of the at least one circuit substrate, the bottom mold has a plurality of lens grooves formed on the top portion thereof to respectively correspond to the lens resin portions, and each lens resin portion has an outer surface tightly contacting the inner surface of each lens groove.

14. The method of claim 13, wherein the top mold includes at least two first positioning elements disposed on the bottom portion thereof, and the bottom mold includes at least two second positioning elements disposed on the top portion thereof to respectively correspond to and mate with the two first positioning elements.

15. The method of claim 13, wherein the top mold includes an encircled protrusion disposed on the bottom portion thereof and a plurality of through grooves formed on the encircled protrusion, and the encircled protrusion tightly contacts the top surface of the bottom mold.

16. A method for making an LED package structure with a deposited-type phosphor layer, comprising the steps of:
(a) providing at least one circuit substrate and a plurality of LED chips, wherein the LED chips are disposed on and electrically connected to the at least one circuit substrate;
(b) providing a mold structure including a top mold and a bottom mold separated from the top mold, wherein the top mold has a first receiving groove formed on a bottom portion thereof, and the bottom mold has a second receiving groove formed on a top portion thereof to correspond to the first receiving groove;
(c) covering the LED chips and filling the second receiving groove with liquid package colloid including phosphor powders;
(d) overturning the at least one circuit substrate and placing the at least one circuit substrate on the top portion of the bottom mold for receiving the LED chips in the second receiving groove;
(e) placing the top mold on the bottom mold and mating the top mold with the bottom mold for positioning the at least one circuit substrate between the top mold and the bottom mold;
(f) simultaneously (1) moving the mold structure by centrifugal force for depositing the phosphor powders on outer surfaces of the LED chips to form a continuous phosphor layer and (2) curing the mold structure for solidifying the liquid package colloid to form a solid package resin body covering the LED chips; and
(g) separating the top mold from the bottom mold and removing the at least one circuit substrate with the LED chips from the mold structure.

17. The method of claim 16, wherein before the step (c), the method further comprises:
cleaning the top mold, the bottom mold and the at least one circuit substrate;
spraying mold-release agent on the surfaces of the top mold and the bottom mold; and
curing the top mold, the bottom mold and the at least one circuit substrate.

18. The method of claim 16, wherein the continuous phosphor layer is composed of a plurality of phosphor powders, and the at least one package resin body is formed by mixing light-permitting silicon with the phosphor powders.

19. The method of claim 16, wherein the continuous phosphor layer is composed of a plurality of phosphor powders, and the at least one package resin body is formed by mixing light-permitting epoxy with the phosphor powders.

20. The method of claim 16, wherein the at least one package resin body includes a bottom resin portion and a plurality of lens resin portions integrally formed on the bottom resin portion, and each lens resin portion is disposed above each LED chip and corresponds to each LED chip.
